(19) United States
(12) Patent Application Publication
(10) Pub. No.: US 2025/0337217 A1
(43) Pub. Date: Oct. 30, 2025

(54) SEMICONDUCTOR INTEGRATED OPTICAL DEVICE

(71) Applicant: Lumentum Operations LLC, San Jose, CA (US)

(72) Inventor: Takeo KAGEYAMA, Yokohama (JP)

(21) Appl. No.: 18/933,566

(22) Filed: Oct. 31, 2024

(30) Foreign Application Priority Data
Apr. 26, 2024 (JP) 2024-072414
Aug. 29, 2024 (JP) 2024-147984

(51) Int. Cl. H01S 5/026

(52) U.S. Cl. CPC H01S 5/0265

(57) ABSTRACT

Provided is a semiconductor integrated optical device with high reliability. The semiconductor integrated optical device includes: a first-conductivity type semiconductor layer; first and second core layers placed on the first-conductivity type semiconductor layer; a first protrusion portion of a first conductivity type which extends from the first-conductivity type semiconductor layer in a direction of growth of the first and second core layers, and which is formed between the first core layer and the second core layer to join the first core layer and the second core layer by a butt joint; a second-conductivity type semiconductor layer placed on the first and second core layers; and a first electrode placed on the second-conductivity type semiconductor layer so as to cover a portion above the first core layer. The second-conductivity type semiconductor layer has a first high-resistance region locally formed therein, the first high-resistance region being formed above the first protrusion portion.

### CROSS-REFERENCE TO RELATED APPLICATIONS

This Patent Application claims priority to Japan Patent Application No. 2024-147984, filed on Aug. 29, 2024, and to Japan Patent Application No. 2024-072414, filed on Apr. 26, 2024. The disclosures of the prior Applications are considered part of and are incorporated by reference into this Patent Application.

### TECHNICAL FIELD

The present disclosure relates generally to a semiconductor integrated optical device.

### BACKGROUND

A plurality of optical function devices can be integrated into a semiconductor integrated optical device. The plurality of optical function devices have semiconductor multilayer structures that are different from one another. One method for forming different semiconductor multilayer structures on the same substrate in an integrated manner is a butt joint method (also referred herein as a “BJ method”). In some cases, in a BJ portion of a structure at which two semiconductor multilayer structures are joined to each other, a part of a substrate forms a side-wall shape control layer between the two semiconductor multilayer structures through a mass transport phenomenon. A semiconductor integrated optical device reduced in deterioration with time can be achieved by forming the side-wall shape control layer and thus reducing occurrence of crystal defects of the semiconductor multilayer structures. In some cases, in order to electrically insulate a joint portion between a plurality of optical function devices, a region having a high resistance is formed by proton implantation therebetween.

### SUMMARY

When a transmission rate in optical communication is increasing, a modulation device, for example, is required to have a quick response. An effective way to improve response rate is to reduce a capacitance of a semiconductor optical device. Price reduction of semiconductor optical devices is advancing as well. In order to satisfy both of the requirements, a reduction in device size is an effective measure. However, a reduction in device size leads to a decrease in withstand voltage against electrostatic discharge (ESD), and consequently to a decrease in reliability.

Some implementations described herein include a semiconductor integrated optical device that has high reliability.

In some implementations, a semiconductor integrated optical device includes: a first-conductivity type semiconductor layer; a first core layer placed on the first-conductivity type semiconductor layer; a second core layer placed on the first-conductivity type semiconductor layer; a first protrusion portion of a first conductivity type which extends from the first-conductivity type semiconductor layer in a direction of growth of the first core layer and the second core layer, and which is formed between the first core layer and the second core layer to join the first core layer and the second core layer by a butt joint; a second-conductivity type semiconductor layer placed on the first core layer and the second core layer; and a first electrode placed on the second-conductivity type semiconductor layer so as to cover a portion above the first core layer. The second-conductivity type semiconductor layer has a first high-resistance region locally formed therein, the first high-resistance region being formed above the first protrusion portion.

### BRIEF DESCRIPTION OF THE DRAWINGS

FIG. 1 is an example of a top view of a semiconductor integrated optical device according to a first example implementation of the present invention.

FIG. 2 is a schematic sectional view taken along the line II-II of the semiconductor integrated optical device illustrated in FIG. 1.

FIG. 3 is a schematic sectional view taken along the line III-III of the semiconductor integrated optical device illustrated in FIG. 1.

FIG. 4A is an enlarged view of a joint portion in which a semiconductor laser portion and a connecting waveguide portion are joined to each other in the schematic sectional view of FIG. 2.

FIG. 4B is a graph for showing an impurity density of a first upper optical confinement layer and a cladding layer of FIG. 4A.

FIG. 5 is an enlarged view of a joint portion in which the connecting waveguide portion and a modulator portion are joined to each other in the schematic sectional view of FIG. 2.

FIG. 6 is a partial enlarged view of a schematic sectional view taken along the line II-II to illustrate Modification Example 1 of the first example implementation.

FIG. 7 is a partial enlarged view of a schematic sectional view taken along the line II-II to illustrate Modification Example 2 of the first example implementation.

FIG. 8 is a schematic sectional view of a semiconductor integrated optical device according to a second example implementation of the present invention.

FIG. 9 is an example of a top view of a semiconductor integrated optical device according to a third example implementation of the present invention.

FIG. 10 is an enlarged view of a schematic sectional view taken along the line X-X of the semiconductor integrated optical device illustrated in FIG. 9.

### DETAILED DESCRIPTION

A specific and detailed description is provided below of example implementations of the present invention with reference to the drawings. Members denoted by a same reference symbol throughout the drawings have a same or an equivalent function, and a repetitive description of the members is omitted. Note that sizes of graphics are not always to scale.

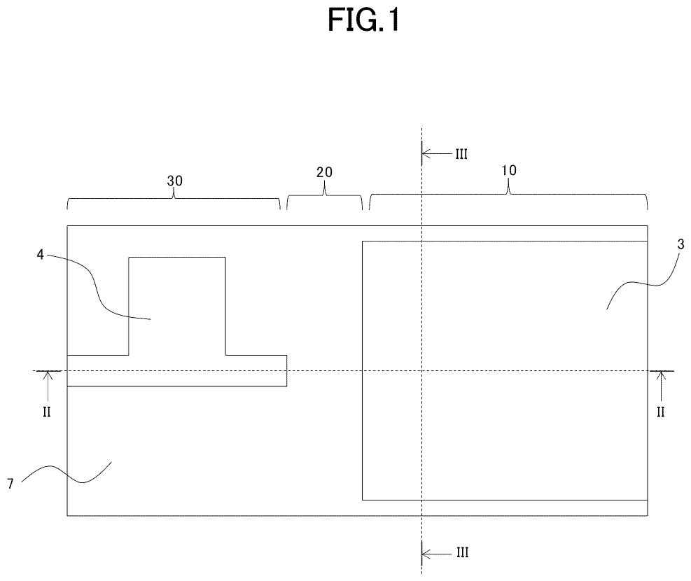

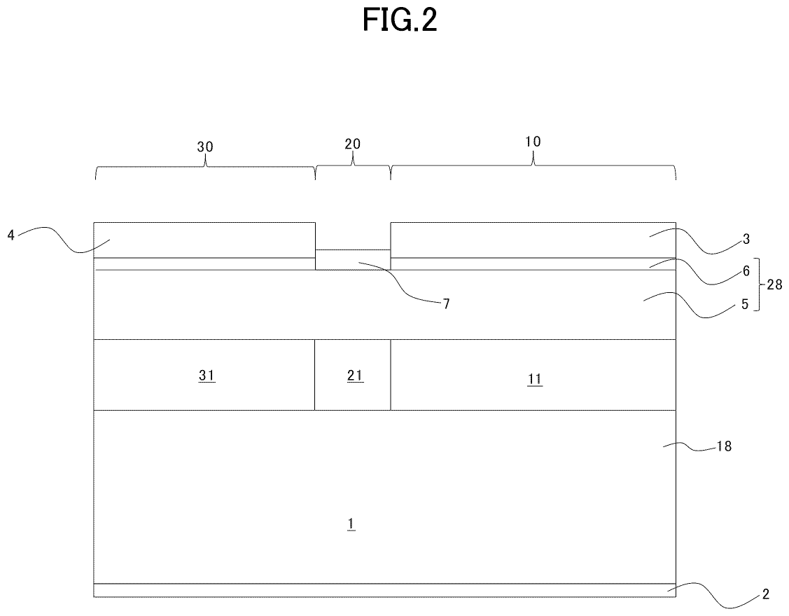

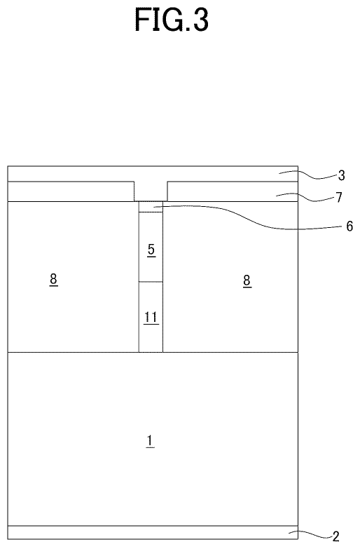

FIG. 1 is a top view of a semiconductor integrated optical device according to a first example implementation of the present invention. FIG. 2 is a schematic sectional view taken along the line II-II of FIG. 1. FIG. 3 is a schematic sectional view taken along the line III-III of FIG. 1. The semiconductor integrated optical device may include three optical function devices integrated on a substrate 1. The three optical function devices may be a semiconductor laser portion 10, a connecting waveguide portion 20, and a modulator portion 30. The modulator portion 30 here may be an electro-absorption modulator, but is not limited thereto. The substrate 1 may be a semiconductor substrate of a first conductivity type, and may be an n-type semiconductor substrate here. The semiconductor integrated optical device may have a counter electrode 2 on a rear surface, a semiconductor laser electrode 3 on a front surface of the semiconductor laser portion 10, and a modulator electrode 4 on a front surface of the modulator portion 30. The counter electrode 2, the semiconductor laser electrode 3, and the modulator electrode 4 may be metal layers. The semiconductor laser electrode 3 may be placed on a second-conductivity type semiconductor layer 28 so as to cover a portion above a first core layer 11 described later. The modulator electrode 4 may be placed on the second-conductivity type semiconductor layer 28 so as to cover a portion above a third core layer 31 described later. A current may be injected between the semiconductor laser electrode 3 and the counter electrode 2 so that the semiconductor laser portion 10 oscillates and emits continuous light. The continuous light emitted by oscillation may be input to the connecting waveguide portion 20 and may be propagated to the modulator portion 30. An electric signal having a high frequency may be applied between the modulator electrode 4 and the counter electrode 2, and the continuous light may be converted into a high-frequency optical signal having a frequency that varies depending on an applied voltage. The high-frequency optical signal may exit from a facet on the modulator portion 30 side. An insulating film 7 may be formed on the front surface of the semiconductor integrated optical device. The counter electrode 2 may be provided for each light function device separately. Although not shown, a low-reflection facet coating film may be formed on the facet on the modulator portion 30 side. A high-reflection facet coating film may be formed on a facet on the semiconductor laser portion 10 side. Alternatively, a low-reflection facet coating film may be formed on the facet on the semiconductor laser portion 10 side as well.

The semiconductor integrated optical device may include a first-conductivity type semiconductor layer 18. The first-conductivity type semiconductor layer 18 may be a part of the substrate 1. The semiconductor laser portion 10 may include the first core layer 11 on the first-conductivity type semiconductor layer 18. The connecting waveguide portion 20 may include a second core layer 21 on the first-conductivity type semiconductor layer 18. The modulator portion 30 may include the third core layer 31 on the first-conductivity type semiconductor layer 18. The first core layer 11 and the second core layer 21 may be joined to each other by a butt joint (BJ) method (hereinafter referred to as a “BJ method”). A BJ joint portion may have a structure in which the first core layer 11 and the second core layer 21 are joined to each other with a front end of the first core layer 11 and a front end of the second core layer 21 butting against each other. The second core layer 21 and the third core layer 31 may be joined to each other by the BJ method. A cladding layer 5 of a second conductivity type and a contact layer 6 of the second conductivity type may be formed above the first core layer 11 and the third core layer 31. The cladding layer 5 of the second conductivity type may be formed on the second core layer 21. The semiconductor layers of the second conductivity type placed on the first core layer 11 may be hereinafter referred to collectively as “second-conductivity type semiconductor layer 28.” The cladding layer 5 and the contact layer 6 here may be the second-conductivity type semiconductor layer 28. The second-conductivity type semiconductor layer 28 may include other layers. The cladding layer 5 may have a structure common to the three optical function devices, and the contact layer 6 may have a structure common to the two optical function devices, but may may have a structure varied from one optical function device to another optical function device. The second conductivity type here may be the “p” type. Alternatively, the first conductivity type may be the “p” type, with the second conductivity type set to the “n” type.

As illustrated in FIG. 3, the semiconductor integrated optical device may be a buried type semiconductor integrated optical device in which both end faces of a mesa structure are buried in a semiconductor layer. The first core layer 11, the cladding layer 5, and the contact layer 6 may form the mesa structure, and a semiconductor buried layer 8 may cover both sides of the mesa structure. The semiconductor buried layer 8 may be a semi-insulating semiconductor layer or a multilayer structure including a p-type semiconductor layer and an n-type semiconductor layer. The structure of FIG. 3 may be substantially the same in the modulator portion 30. The structure of FIG. 3 may be substantially the same in the connecting waveguide portion 20 except that the contact layer 6 and the semiconductor laser electrode 3 are not provided and the insulating film 7 is placed on the mesa structure. The semiconductor integrated optical device may be of a ridge type in which each core layer does not have a mesa structure.

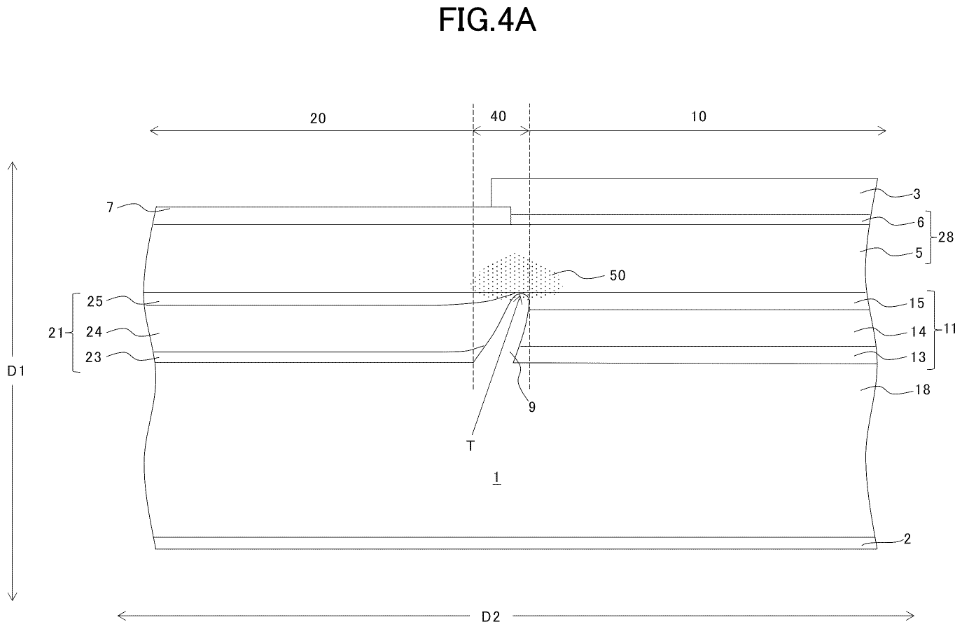

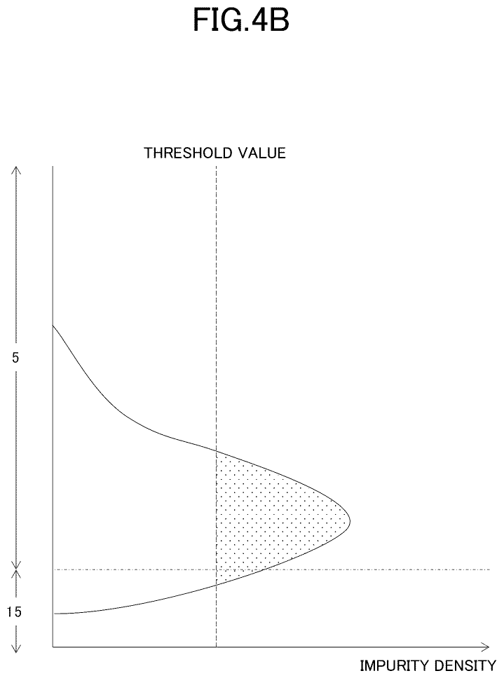

FIG. 4A is an enlarged view of a joint portion in which the semiconductor laser portion 10 and the connecting waveguide portion 20 may be joined to each other. FIG. 4B is a graph for schematically showing an impurity density of a first upper optical confinement layer (hereinafter referred to as “first upper SCH layer”) 15 and the cladding layer 5 in a region immediately above a first protrusion portion 9. The first core layer 11 of the semiconductor laser portion 10 and the second core layer 21 of the connecting waveguide portion 20 may be joined to each other by the BJ method.

The first core layer 11 may include a first lower optical confinement layer (hereinafter referred to as “first lower SCH layer”) 13, an active layer 14, and a first upper SCH layer 15. The first lower SCH layer 13 may be of the same conductivity type as the conductivity type of the first-conductivity type semiconductor layer 18 and may be an n-type layer. The active layer 14 may be a multiple quantum well layer (hereinafter referred to as an “MQW layer”), and may be an i-type semiconductor layer which contains no intentionally added impurities. The first upper SCH layer 15 may be of the same conductivity type as the conductivity type of the second-conductivity type semiconductor layer 28 and, here, may be a p-type semiconductor layer. Although not shown, a grating layer may be included between the first upper SCH layer 15 and the cladding layer 5. The grating layer may be positioned between the substrate 1 and the first lower SCH layer 13. The semiconductor laser portion 10 may be set so as to oscillate and emit light in a wavelength band of 1.3 micrometers (μm) or 1.55 μm. The semiconductor layers given here are merely an example, and other layers may be included. The first lower SCH layer 13 and the first upper SCH layer 15 may be i-type semiconductor layers which contain no intentionally added impurities.

The second core layer 21 may include a second lower SCH layer 23, a waveguide layer 24, and a second upper SCH layer 25. The second lower SCH layer 23 may be of the same conductivity type as the conductivity type of the first-conductivity type semiconductor layer 18 and, here, may be an n-type layer. The waveguide layer 24 may be a bulk semiconductor layer, and may be an i-type semiconductor layer which contains no intentionally added impurities. The second upper SCH layer 25 may be of the same conductivity type as the conductivity type of the second-conductivity type semiconductor layer 28 and, here, may be a p-type semiconductor layer. The semiconductor layers given here are merely an example, and other layers may be included. The second lower SCH layer 23 and the second upper SCH layer 25 may be i-type semiconductor layers which contain no intentionally added impurities. The second-conductivity type semiconductor layer 28 may be also placed on the second core layer 21.

The first protrusion portion 9 of the first conductivity type may be included at least in a part of a space between the first core layer 11 and the second core layer 21. The first protrusion portion 9 extends from the first-conductivity type semiconductor layer 18 in a direction of growth of the first core layer 11 and the second core layer 21, and may be formed between the first core layer 11 and the second core layer 21 to join the first core layer 11 and the second core layer 21 to each other by a butt joint. Specifically, the first protrusion portion 9 can reduce a drop in optical coupling ratio in a BJ joint portion. The first protrusion portion 9 may be formed unitarily with the first-conductivity type semiconductor layer 18, and may have a shape slanted toward the semiconductor laser portion 10. The first-conductivity type semiconductor layer 18 here may be a part of the substrate 1. Accordingly, the first protrusion portion 9 may be the same n-type semiconductor layer as the substrate 1, and may be formed from the same material as the material of the substrate 1. In the first example implementation, the substrate 1 and the first protrusion portion 9 may be an n-type InP layer. There may be a case in which a buffer layer is formed between the substrate 1 and the first core layer 11 and the second core layer 21 from a material of the same conductivity type as the conductivity type of the substrate 1. In this case, the buffer layer may be the first-conductivity type semiconductor layer 18. The first protrusion portion 9 may be a recrystallized region in which a part of the first-conductivity type semiconductor layer 18 is formed along a side wall of the first core layer 11 through a mass transport phenomenon when or before the second core layer 21 may be grown. The first protrusion portion 9 may be formed in the entire region in which the first core layer 11 and the second core layer 21 are in contact with each other. The second core layer 21 around the first BJ joint portion 40 may have a shape that is overall slanted along the first protrusion portion 9. In the first example implementation, the first protrusion portion 9 may be formed slanted toward the semiconductor laser portion 10 because the second core layer 21 is formed after the first core layer 11 is formed. In a case in which the second core layer 21 is formed first, the first protrusion portion 9 may slant toward the connecting waveguide portion 20. Although a top surface of the first core layer 11 (a top surface of the first upper SCH layer 15) and a top surface of the second core layer 21 (a top surface of the second upper SCH layer 25) may be flush with each other in FIG. 4A, there may be a level difference therebetween. The second core layer 21 may bulge toward the cladding layer 5 past a height of a flat end portion of the second upper SCH layer 25 around the first BJ joint portion 40.

When viewed from a direction in which the semiconductor layers are grown (hereinafter referred to as “first direction D1”), a front end T of the first protrusion portion 9 may be formed to a position past the active layer 14. That is, the front end T may reach halfway through the first upper SCH layer 15. In some implementations, a region in which the first protrusion portion 9 is present in plan view may be defined as the first BJ joint portion 40. As illustrated in FIG. 4A, the first protrusion portion 9 starts to rise from the first-conductivity type semiconductor layer 18 at an end portion of the first BJ joint portion 40 on the connecting waveguide portion 20 side. Meanwhile, on the semiconductor laser portion 10 side, the first protrusion portion 9 protrudes most toward the first core layer 11 in a direction in which the mesa structure extends (hereinafter referred to as “second direction D2”), instead of starting to rise from the first-conductivity type semiconductor layer 18.

The semiconductor integrated optical device may include a first high-resistance region 50 locally formed above the first protrusion portion 9. Specifically, the first high-resistance region 50 may be formed in an upper portion of the first BJ joint portion 40. The first high-resistance region 50 may be formed by implanting impurity ions into the cladding layer 5 of the second conductivity type (here, the “p” type). In this case, hydrogen ions (protons) may be implanted. Other materials thereof include He and Si. In a region in which impurity ions are implanted, p-type carriers may be deactivated, and the region may have a higher resistance than a region in which impurity ions are not implanted. The impurity ions may be implanted from a front surface (here, the contact layer 6) side of a semiconductor multilayer after the semiconductor multilayer is grown. Thus, an interface for the region in which impurity ions are implanted may not be clearer than a semiconductor layer interface formed during epitaxial growth, and the first high-resistance region 50 may be formed with a distribution. The distribution here may be a distribution of resistivity. The distribution of resistivity may be proportional to a density (volume density) of implanted impurity ions (here, protons). Accordingly, the distribution of resistivity may be read substantially as a distribution of the density of impurity ions. The impurity ions may be implanted as ions, but may be not always kept in an ion state after having been implanted into each semiconductor layer. The impurity ions that have been implanted into each semiconductor layer may be hereinafter referred to simply as “impurities.” The resistivity and the impurity density may be approximately proportional to each other, but may not always be proportional to each other (the resistivity becomes less likely to change) when implanted impurity ions greatly exceed a carrier concentration of each semiconductor layer. Specifically, impurities contained in the first upper optical confinement layer 15 and the cladding layer 5 may be distributed in a region immediately above the first protrusion portion 9 as shown in FIG. 4B. The broken line of FIG. 4B indicates a threshold value at which each semiconductor layer may be deactivated, and a resistivity increases in a region in which the impurity density exceeds the threshold value. As shown in FIG. 4B, in the first example implementation, a center of the distribution of the first high-resistance region 50 in the first direction D1 may be positioned lower than a center of the cladding layer 5 (the first protrusion portion 9 side and the lower side of FIG. 4B). Meanwhile, a center of the first high-resistance region 50 in the second direction D2 may be positioned at the front end T. The center of the distribution here means a site at which the impurity density is the highest. In other words, in the first direction D1, the impurity density of a region below the center of the cladding layer 5 may be higher than the density of a region above the center. In other words, the resistivity of the first high-resistance region 50 may be higher in a region below the center of the cladding layer 5 than in a region above the center. Meanwhile, in the second direction D2, the impurity density may be the highest around the front end T, and the density decreases as the distance from the front end T increases. It is not required for a portion above the front end T to have the highest density in the second direction D2, and it suffices that the density of the entire first BJ joint portion 40 may be higher than those of the other regions. The first high-resistance region 50 may not only be placed in the first BJ joint portion 40 but also placed so as to spread to the semiconductor laser portion 10 and the connecting waveguide portion 20 in the first example implementation, but the present invention is not limited thereto. For example, the first high-resistance region 50 may be placed only in the first BJ joint portion 40, or may be placed only in the first BJ joint portion 40 and the semiconductor laser portion 10. However, when the first high-resistance region 50 excessively spreads toward the semiconductor laser portion 10 to be energized, an electric field may not be sufficiently applied to a region of the semiconductor laser portion 10 on the first BJ joint portion 40 side, and optical characteristics may deteriorate. Accordingly, the first high-resistance region 50 may be desired to fit in a region within 5 μm from the first BJ joint portion 40.

In this case, in order to achieve sufficiently high resistance, the impurity density may be preferred to be equal to or higher than the carrier density of each semiconductor layer in the region to be subjected to deactivation. However, when the impurity density is sufficiently higher than the carrier density, excessively implanted impurities may migrate through each semiconductor layer in another manufacturing step and affect characteristics. Accordingly, the impurity density may be preferred to be 1 or more and less than 10 times the carrier density.

The first high-resistance region 50 may be placed also in parts of the first upper SCH layer 15, the first protrusion portion 9, and the second upper SCH layer 25. However, the first high-resistance region 50 may be preferred not to be placed in the active layer 14. The active layer 14 may be a region in which a current is injected and from which light is emitted, and hence optical characteristics may deteriorate due to the placement of the first high-resistance region 50. Thus, the first high-resistance region 50 may be preferred to be placed only in the cladding layer 5, but as described above, the first high-resistance region 50 may be formed by implanting impurity ions, and hence there may be a case in which the impurity ions may be partially implanted into the first core layer 11 and the second core layer 21 due to manufacturing variation. The first high-resistance region 50 may have a substantially droplet-like shape as illustrated in FIG. 4A.

The first protrusion portion 9 may have an effect of reducing a drop in optical coupling ratio in the first BJ joint portion 40. However, a test conducted to check an electrostatic discharge (ESD) withstand voltage of the semiconductor laser portion 10 may indicated that general specifications are met, but crystals around the first BJ joint portion 40 deteriorate first when a voltage higher than a standard is applied. This may be due to the following mechanism. A voltage applied to the semiconductor laser electrode 3 is transmitted via the contact layer 6 of the second conductivity type to the cladding layer 5. The voltage is applied toward the first-conductivity type semiconductor layer 18 (the substrate 1) but, because the first protrusion portion 9 (in particular, the front end T) which is the n-type semiconductor layer is in close proximity to the cladding layer 5 which is the p-type layer, a voltage concentrates around the front end T. As a result, deterioration of crystals has been caused by ESD around the first protrusion portion 9, that is, around the first BJ joint portion 40. A crystal quality around the first BJ joint portion 40 is poor compared to sites apart from the first BJ joint portion 40, and the poor crystal quality is another reason for the tendency toward deterioration around the first BJ joint portion 40. In comparison, in the first example implementation, the first high-resistance region 50 may be placed in the cladding layer 5 above the first protrusion portion 9. Concentration of an electric field at the first protrusion portion 9 can consequently be reduced, deterioration of crystals around the first BJ joint portion 40 can be suppressed, and a semiconductor integrated optical device high in reliability can be achieved.

In order to sufficiently obtain the above-mentioned effects, it is effective that a region having a high resistance, that is, a region in which impurities are implanted is placed above and close to the first protrusion portion 9. Further, in the first direction D1, the impurity density may be higher on a side below the center of the cladding layer 5, that is, on a side close to the first protrusion portion 9, thereby deactivating the p-type carriers in a region close to the first protrusion portion 9 and increasing the resistance of the region, and concentration of a voltage can consequently be sufficiently reduced. In other words, the resistivity immediately above the first protrusion portion 9 may be higher than those of the other regions, thereby suppressing concentration of a voltage at the first protrusion portion 9. When the impurity density is higher in a portion close to an upper portion of the cladding layer 5, the voltage applied to the semiconductor laser electrode 3 may not be strongly applied to the upper portion of the cladding layer 5 but may expand in the cladding layer 5 toward the front end T, thereby causing concentration of the voltage at the front end T. Accordingly, as illustrated in FIG. 4A, the impurity density may be preferred to be higher on the side below the center of the cladding layer 5.

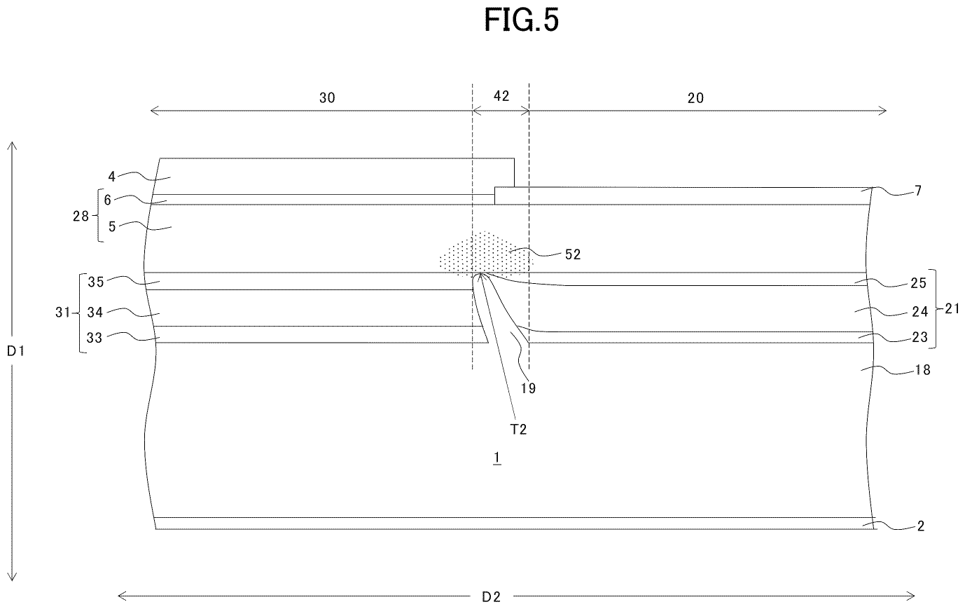

FIG. 5 is an enlarged view around a joint portion in which the connecting waveguide portion 20 and the modulator portion 30 are joined to each other. The second core layer 21 of the connecting waveguide portion 20 and the third core layer 31 of the modulator portion 30 may be joined by the BJ method.

The third core layer 31 may include a third lower SCH layer 33, an absorption layer 34, and a third upper SCH layer 35. The third lower SCH layer 33 may be of the same conductivity type as the conductivity type of the first-conductivity type semiconductor layer 18. Here, the third lower SCH layer 33 may be an n-type layer. The absorption layer 34 may be an MQW layer, and may be an i-type semiconductor layer which contains no intentionally added impurities. The third upper SCH layer 35 may be of the same conductivity type as the conductivity type of the second-conductivity type semiconductor layer 28 and, here, may be a p-type semiconductor layer. The second-conductivity type semiconductor layer 28 may be placed on the third core layer 31 as well. The modulator portion 30 may be an optical function device that converts light emitted from the semiconductor laser portion 10 by oscillation into a high-frequency optical signal. The semiconductor layers given here may be merely an example, and other layers may be included. The third lower SCH layer 33 and the third upper SCH layer 35 may be i-type semiconductor layers which contain no intentionally added impurities.

A second protrusion portion 19 may be included in a part of a space between the second core layer 21 and the third core layer 31. The second protrusion portion 19 may extend from the first-conductivity type semiconductor layer 18 in a direction of growth of the third core layer 31, and may be formed between the second core layer 21 and the third core layer 31 to join the second core layer 21 and the third core layer 31 to each other by a butt joint. Specifically, the second protrusion portion 19 may be formed unitarily with the first-conductivity type semiconductor layer 18, and may have a shape slanted toward the modulator portion 30. The first-conductivity type semiconductor layer 18 here may be the substrate 1. Accordingly, the second protrusion portion 19 may be of the same first conductivity type (n-type semiconductor layer) as the conductivity type of the substrate 1, and may be formed from the same material as the material of the substrate 1. In the first example implementation, the second protrusion portion 19 may be an n-type InP layer. The second core layer 21 around the second BJ joint portion 42 may have a shape that is overall slanted along the second protrusion portion 19. In the first example implementation, the second protrusion portion 19 may be formed slanted toward the modulator portion 30 because the second core layer 21 is formed after the third core layer 31 is formed. In a case in which the second core layer 21 is formed first, the second protrusion portion 19 slants toward the connecting waveguide portion 20. Although the top surface of the second core layer 21 (the top surface of the second upper SCH layer 25) and a top surface of the third core layer 31 (a top surface of the third upper SCH layer 35) may be flush with each other in FIG. 5, there may be a level difference therebetween. The second core layer 21 may bulge toward the cladding layer 5 past a height of a flat end portion of the third upper SCH layer 35 around the second BJ joint portion 42.

When viewed from the first direction D1, the second protrusion portion 19 may be formed so that a front end T2 of the second protrusion portion 19 reaches a position past the absorption layer 34. The front end T2 reaches halfway through the third upper SCH layer 35. In the present application, as in FIG. 4A, a region in which the second protrusion portion 19 protrudes from the first-conductivity type semiconductor layer 18 (the substrate 1) may be defined as the second BJ joint portion 42. As illustrated in FIG. 5, the second protrusion portion 19 starts to rise from the first-conductivity type semiconductor layer 18 at an end portion of the second BJ joint portion 42 on the connecting waveguide portion 20 side. Meanwhile, on the modulator portion 30 side, the second protrusion portion 19 protrudes most toward the third core layer 31 in the second direction D2, instead of starting to rise from the first-conductivity type semiconductor layer 18.

As in the first BJ joint portion 40, a second high-resistance region 52 may be locally formed above the second protrusion portion 19 also in the second BJ joint portion 42. A feature of the second high-resistance region 52 may be the same as that of the first high-resistance region 50. Accordingly, in the ESD withstand voltage test in which a voltage is applied between the modulator electrode 4 and the counter electrode 2, concentration of the voltage at the second protrusion portion 19 may be reduced, thereby improving the ESD withstand voltage in the second BJ joint portion 42 region, and a semiconductor integrated optical device high in reliability can therefore be achieved.

The first high-resistance region 50 and the second high-resistance region 52 may be formed by implanting impurity ions, and hence interfaces therefor may not be clear. In FIG. 4A, FIG. 5, and the subsequent figures, interfaces for the first high-resistance region 50 and the second high-resistance region 52 are merely illustrated for the sake of description.

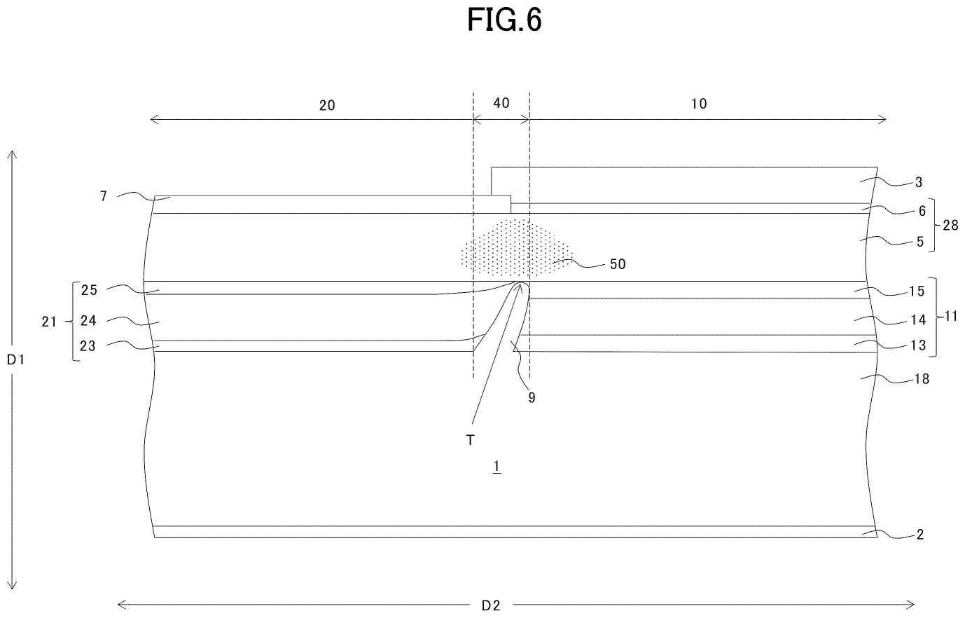

FIG. 6 is a schematic sectional view taken along the line II-II to illustrate regions around the first BJ joint portion 40 of a semiconductor integrated optical device according to Modification Example 1 of the first example implementation. In Modification Example 1, in the first direction D1, the first high-resistance region 50 may be formed in a region that starts from a region close to the top surface of the cladding layer 5 and may not reach the first core layer 11 and the second core layer 21. However, as illustrated in FIG. 6, the first high-resistance region 50 may have a substantially droplet shape in which the lower side thereof is wider than the upper side. The first high-resistance region 50 may be preferred to be placed so as not to ideally reach the active layer 14 but to such an extent as to be in contact with the front end T. However, the first high-resistance region 50 may be formed by implanting impurity ions (protons), and hence variation in positional precision in the first direction D1 occurs. When the first high-resistance region 50 is formed so as to reliably avoid reaching the active layer 14, there is a possibility that impurity ions are not implanted up to the lower surface of the cladding layer 5. However, in the first direction D1, the impurity density in the cladding layer 5 may be higher on the side (the first protrusion portion 9 side) below the center of the cladding layer 5 than on the side above the center. As a result, concentration of the voltage at the front end T is reduced, and a semiconductor integrated optical device high in ESD withstand voltage (high in reliability) is achieved.

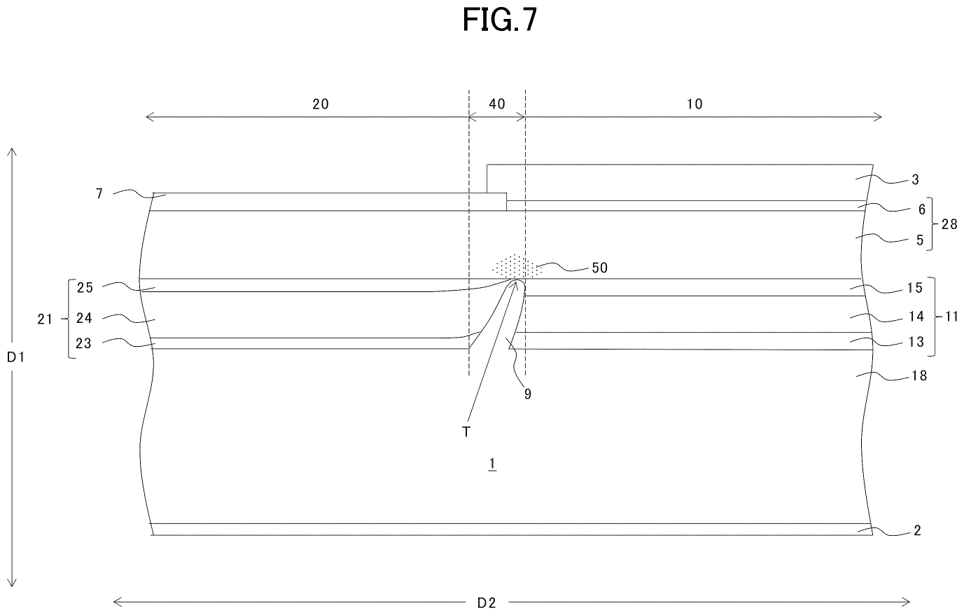

FIG. 7 is a schematic sectional view taken along the line II-II to illustrate regions around the first BJ joint portion 40 of a semiconductor integrated optical device according to Modification Example 2 of the first example implementation. In Modification Example 2, the first high-resistance region 50 may not be located in the connecting waveguide portion 20 in the second direction D2. The first high-resistance region 50 may be placed only in the first BJ joint portion 40 and the semiconductor laser portion 10. Accordingly, as compared to the first example implementation, an area in which the first high-resistance region 50 is placed is small. Needless to say, the above-mentioned effects may be obtained in Modification Example 2 as well.

In the first example implementation, Modification Example 1, and Modification Example 2, the contact layer 6 and the semiconductor laser electrode 3 may overlap with each other in the first BJ joint portion 40 in the second direction D2. Accordingly, a voltage applied to the semiconductor laser electrode 3 is likely to be applied to the first protrusion portion 9. When the contact layer 6 and the semiconductor laser electrode 3 are placed so as not to overlap with the first BJ joint portion 40 (the first protrusion portion 9), voltage application to the first protrusion portion 9 tends to be relaxed. However, the voltage spreads inside the cladding layer 5, and hence there is no change in that the voltage is likely to concentrate at the first protrusion portion 9, even in a configuration in which the contact layer 6 and the semiconductor laser electrode 3 do not overlap with the first BJ joint portion 40. As a matter of course, when front ends of the contact layer 6 and the semiconductor laser electrode 3 are distanced from the first BJ joint portion 40 to such an extent that the voltage does not spread to the first protrusion portion 9, crystal deterioration starting from the first BJ joint portion 40 can be reduced. However, in this structure, a region in which no voltage is applied is formed in the active layer 14, and therefore optical characteristics may be affected. Accordingly, from the viewpoint of optical characteristics, the contact layer 6 and the semiconductor laser electrode 3 may be preferred to overlap with a part of the first BJ joint portion 40. With such a structure, some implementations improve the ESD withstand voltage and achieve a semiconductor integrated optical device high in reliability. Even in a case in which the contact layer 6 and the semiconductor laser electrode 3 do not overlap with the first BJ joint portion 40, the effects may be obtained when the front ends of the contact layer 6 and the semiconductor laser electrode 3 are close to the first BJ joint portion 40. For example, when a distance between the first BJ joint portion 40 and each of the front ends of the contact layer 6 and the semiconductor laser electrode 3 in the second direction D2 is 5 μm or less, the effects are obtained. Needless to say, the description given above is also applicable to the second BJ joint portion 42, which may be a site at which the modulator portion 30 and the connecting waveguide portion 20 are joined to each other.

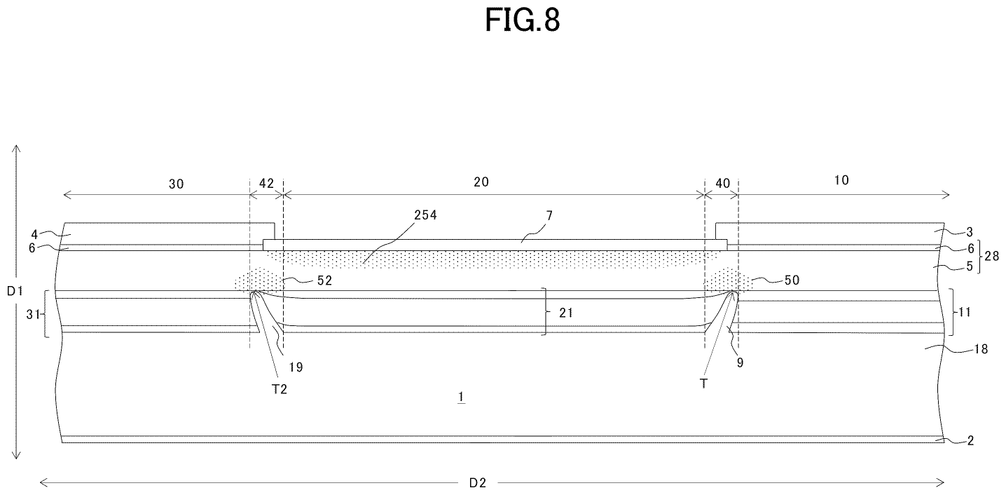

FIG. 8 is a schematic sectional view taken along a direction conforming to a mesa structure of a semiconductor integrated optical device according to a second example implementation of the present invention. A difference from the first example implementation is that a third high-resistance region 254 may be placed in the connecting waveguide portion 20 for the purpose of electrical insulation. The first high-resistance region 50 and the second high-resistance region 52 placed in the first BJ joint portion 40 and the second BJ joint portion 42, respectively, may be the same as those in the first example implementation.

Mutually different electric signals may be input to the semiconductor laser portion 10 and the modulator portion 30. Meanwhile, the semiconductor laser portion 10 and the modulator portion 30 can provide electrical continuity to each other through the cladding layer 5. Accordingly, in some cases, the electric signals input to the semiconductor laser portion 10 and the modulator portion 30 may affect each other. As an electrical insulating property between the semiconductor laser portion 10 and the modulator portion 30 is increased, characteristics as a semiconductor integrated optical device are further improved. In the second example implementation, the third high-resistance region 254 may be placed in the cladding layer 5 of the connecting waveguide portion 20. The third high-resistance region 254 may be formed by implanting impurity ions, here protons, as in the cases of the first high-resistance region 50 and the second high-resistance region 52. However, a density distribution of impurities in the third high-resistance region 254 differs from the first high-resistance region 50 and the second high-resistance region 52 in the first direction D1. In the first direction D1, the density distribution of impurities in the third high-resistance region 254 may be larger on the side (the insulating film 7 side) above the center of the cladding layer 5 than on the side (the second core layer 21 side) below the center. In other words, the resistivity of the third high-resistance region 254 may be higher on the side above the center of the cladding layer 5 than on the side below the center. Voltages applied to the semiconductor laser electrode 3 and the modulator electrode 4 may be higher on an upper side of the cladding layer 5. Accordingly, crosstalk between the two electric signals may be liable to occur on the upper side of the cladding layer 5. Making the impurity density of the third high-resistance region 254 higher on the upper side of the cladding layer 5 can reduce crosstalk between electric signals, and can consequently improve the electrical insulating property between the semiconductor laser portion 10 and the modulator portion 30. The impurities contained in the first high-resistance region 50 and the second high-resistance region 52 and the impurities contained in the third high-resistance region 254 may be the same material or different from each other. The impurities contained in the first high-resistance region 50 and the second high-resistance region 52 are preferred to be the same material.

The third high-resistance region 254 may extend to the first BJ joint portions 40 and the second BJ joint portion 42. In the second example implementation, the first high-resistance region 50 and the second high-resistance region 52 may be separated from the third high-resistance region 254 in the first BJ joint portions 40 and the second BJ joint portion 42, respectively. However, those regions may be continuous. When the second high-resistance region 52 is placed in a region extending to the second core layer 21, an extremely large number of impurity ions may be assumed to have been implanted in the cladding layer 5. Those impurities may migrate in a manufacturing process, and when the impurities migrate (diffuse) to the waveguide layer 24, the active layer 14, and the absorption layer 34, reliability and characteristics of those layers may deteriorate. Accordingly, impurities (high-resistance region) preferred to be placed within a range in which each purpose thereof is achieved. In the second example implementation, it may be preferred to make the impurity density of the first high-resistance region 50 and the second high-resistance region 52 higher on the lower side of the cladding layer 5 and make the impurity density of the third high-resistance region 254 higher on the upper side of the cladding layer 5.

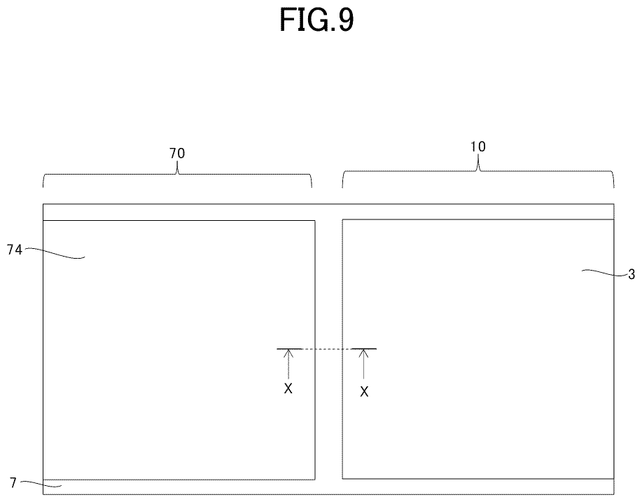

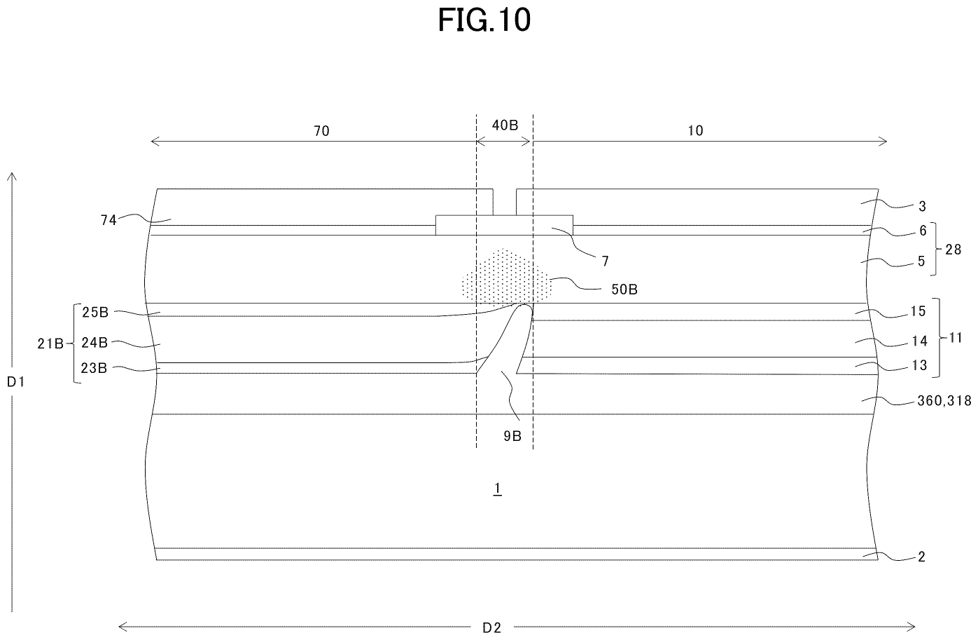

FIG. 9 is a top view of a semiconductor integrated optical device according to a third example implementation of the present invention. FIG. 10 is a schematic sectional view taken along the line X-X of FIG. 9. The semiconductor integrated optical device of the third example implementation integrates the semiconductor laser portion 10 and an optical amplification portion 70 on the substrate 1. That is, the semiconductor integrated optical device of the third example implementation may be a semiconductor integrated optical device in which two optical function devices are integrated. The semiconductor laser portion 10 may have the same structure as that given in the first example implementation.

The optical amplification portion 70 may have a function of amplifying light emitted from the semiconductor laser portion 10. The optical amplification portion 70 may include a second core layer 21B. The second core layer 21B may include a second lower SCH layer 23B, an optical amplification layer 24B, and a second upper SCH layer 25B. The second lower SCH layer 23B may be of the first conductivity type, and the second upper SCH layer 25B may be of the second conductivity type. The optical amplification layer 24B may be an MQW layer. The optical amplification portion 70 may include an optical amplification electrode 74. The semiconductor layers given here may be merely an example, and other layers may be included. The second lower SCH layer 23B and the second upper SCH layer 25B may be i-type semiconductor layers which contain no intentionally added impurities.

A buffer layer 360 of the first conductivity type may be placed between the substrate 1 and the first core layer 11 and the second core layer 21B. The buffer layer 360 of the first conductivity type may be of the same conductivity type as the conductivity type of the substrate 1 and, here, may be also a first-conductivity type semiconductor layer 318.

The first core layer 11 and the second core layer 21B may be joined to each other by the BJ method in a first BJ joint portion 40B, which may include a first protrusion portion 9B. As in the case of the first protrusion portion 9 in the first example implementation, the first protrusion portion 9B may be a recrystallized region in which a part of the first-conductivity type semiconductor layer 18 is formed along a side wall of the first core layer 11 through a mass transport phenomenon.

A first high-resistance region 50B may be formed in the cladding layer 5 above the first protrusion portion 9B. The first high-resistance region 50B here plays both a role of reducing concentration of an electric field at the first protrusion portion 9B and a role of providing electrical insulation between the semiconductor laser portion 10 and the optical amplification portion 70. Accordingly, while the density distribution of impurities in the first high-resistance region 50B may be larger on the lower side of the cladding layer 5 than on the upper side in the first direction D1, the impurity density on the upper side of the cladding layer 5 may exceed the threshold value at which each semiconductor layer is deactivated. The concentration of the electric field at the first protrusion portion 9B may be reduced when impurities for deactivating at least carriers in the cladding layer 5 are placed above the first protrusion portion 9B and on the side (the first protrusion portion 9B side) below the center of the cladding layer 5 in the first direction D1. Some of the impurities preferably reach semiconductor layers below the cladding layer 5, for example, the first upper SCH layer 15, the second upper SCH layer 25B, and the first protrusion portion 9B, thereby further enhancing the effects. However, impurities may be preferred not to be placed in the active layer 14 and the optical amplification layer 24B.

In the example implementations described above, the substrate may be a conductive substrate, but is not limited thereto. An insulating (including semi-insulating) substrate may also be used. In a case of using an insulating substrate, a first-conductivity type semiconductor layer (e.g., a buffer layer) may be placed between the substrate and the core layer, and a conductivity type of the protrusion portion may be the same as the conductivity type of the first-conductivity type semiconductor layer. A counter electrode may be placed on a surface on which the core layers may be formed, instead of on a rear side of the substrate.

The present invention gives high reliability to a semiconductor integrated optical device in which a plurality of optical function devices are joined by a butt joint to be integrated on a single substrate. This is achieved by providing a protrusion portion between respective core layers of two optical function devices and placing a high-resistance region above the protrusion portion. The protrusion portion is a semiconductor layer of the first conductivity type. A second-conductivity type semiconductor layer is placed on the core layer and the protrusion portion, and the high-resistance region is placed in the second-conductivity type semiconductor layer. The high-resistance region is formed by implanting impurity ions. The impurity ions deactivate carriers in the second-conductivity type semiconductor layer to increase the resistivity of the region in which the impurities are implanted. The high-resistance region is thus formed. The density of impurities placed in the second-conductivity type semiconductor layer is higher in a portion close to the core layer than in a portion far from the core layer in the direction of growth of the semiconductor layers. The examples of the impurities include hydrogen, helium, and Si.

While there have been described what are at present considered to be certain example implementations of the invention, it will be understood that various modifications may be made thereto, and it is intended that the appended claims cover all such modifications as fall within the true spirit and scope of the invention.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

As used herein, satisfying a threshold may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. A semiconductor integrated optical device, comprising:
a first-conductivity type semiconductor layer;
a first core layer placed on the first-conductivity type semiconductor layer;
a second core layer placed on the first-conductivity type semiconductor layer;
a first protrusion portion of a first conductivity type which extends from the first-conductivity type semiconductor layer in a direction of growth of the first core layer and the second core layer, and which is formed between the first core layer and the second core layer to join the first core layer and the second core layer by a butt joint;
a second-conductivity type semiconductor layer placed on the first core layer and the second core layer; and
a first electrode placed on the second-conductivity type semiconductor layer so as to cover a portion above the first core layer,
wherein the second-conductivity type semiconductor layer has a first high-resistance region locally formed therein, the first high-resistance region being formed above the first protrusion portion.

2. The semiconductor integrated optical device according to claim 1, wherein the first high-resistance region is formed by placing first impurities in the second-conductivity type semiconductor layer.

3. The semiconductor integrated optical device according to claim 2,
wherein the second-conductivity type semiconductor layer includes a cladding layer of a second conductivity type that is in contact with the first core layer, and
wherein the first high-resistance region is placed at least in the cladding layer.

4. The semiconductor integrated optical device according to claim 3, wherein a density of the first impurities in the first high-resistance region is higher on the first protrusion portion side than on the first electrode side when viewed from a center of the cladding layer in the direction of growth.

5. The semiconductor integrated optical device according to claim 3, wherein a resistivity of the first high-resistance region is higher on the first protrusion portion side than on the first electrode side when viewed from a center of the cladding layer in the direction of growth.

6. The semiconductor integrated optical device according to claim 3, wherein the first high-resistance region is placed in a part of the first protrusion portion.

7. The semiconductor integrated optical device according to claim 2, wherein a density of the first impurities in the first high-resistance region becomes lower at a position farther from the first protrusion portion in plan view.

8. The semiconductor integrated optical device according to claim 2,
wherein the first protrusion portion includes a front end portion that is closest to the second-conductivity type semiconductor layer, and
wherein a density of the first impurities in the first high-resistance region is the highest in a portion above the front end portion.

9. The semiconductor integrated optical device according to claim 2,
wherein the first core layer has a first lower optical confinement layer, an active layer, and a first upper optical confinement layer grown in the stated order from the first-conductivity type semiconductor layer side, and
wherein the first high-resistance region is placed in a part of the first upper optical confinement layer.

10. The semiconductor integrated optical device according to claim 2,
wherein the second core layer has a second lower optical confinement layer, a waveguide layer, and a second upper optical confinement layer grown in the stated order from the first-conductivity type semiconductor layer side, and
wherein the first high-resistance region is placed in a part of the second upper optical confinement layer.

11. The semiconductor integrated optical device according to claim 2, wherein the first impurities comprise one of hydrogen, helium, or silicon.

12. The semiconductor integrated optical device according to claim 2, further comprising:
a third core layer placed on the first-conductivity type semiconductor layer on a side opposite to the first core layer with respect to the second core layer;
a second protrusion portion of the first conductivity type which extends from the first-conductivity type semiconductor layer in a direction of growth of the third core layer, and which is formed between the second core layer and the third core layer to join the second core layer and the third core layer by a butt joint; and
a second electrode placed so as to cover a portion above the third core layer,
wherein the second-conductivity type semiconductor layer is placed on the third core layer as well,
wherein the second electrode is placed on the second-conductivity type semiconductor layer, and
wherein the semiconductor integrated optical device further comprises a second high-resistance region that is locally formed above the second protrusion portion in the second-conductivity type semiconductor layer.

13. The semiconductor integrated optical device according to claim 12, wherein the second high-resistance region is formed by placing second impurities in the second-conductivity type semiconductor layer.

14. The semiconductor integrated optical device according to claim 12, wherein the second-conductivity type semiconductor layer on the second core layer has a third high-resistance region placed therein.

15. The semiconductor integrated optical device according to claim 14, wherein the third high-resistance region is formed by placing third impurities in the second-conductivity type semiconductor layer.

16. The semiconductor integrated optical device according to claim 15,
wherein the second-conductivity type semiconductor layer includes a cladding layer of a second conductivity type that is in contact with the first core layer, and
wherein a density of the third impurities in the third high-resistance region is lower on the second core layer side than on a side opposite to the second core layer side when viewed from a center of the cladding layer in the direction of growth.

17. The semiconductor integrated optical device according to claim 1, wherein the first protrusion portion is formed unitarily with the first-conductivity type semiconductor layer.

18. The semiconductor integrated optical device according to claim 17, wherein the first protrusion portion is formed from the same material as a material of the first-conductivity type semiconductor layer.

19. The semiconductor integrated optical device according to claim 13, wherein the first impurities and the second impurities comprise the same material.

20. The semiconductor integrated optical device according to claim 15, wherein the first impurities and the third impurities comprise the same material.
